(19) United States
(12) Patent Application Publication
(10) Pub. No.: US 2021/0028869 A1
(43) Pub. Date: Jan. 28, 2021

(54) Test Method, Transmit Device, Test Device, and Test System

(71) Applicant: Huawei Technologies Co., Ltd., Shenzhen (CN)

(72) Inventors: Bo Hao, Xi'an (CN); Xiaopeng Li, Xi'an (CN); Xubo Zhao, Xi'an (CN)

(21) Appl. No.: 17/068,300

(22) Filed: Oct. 12, 2020

Related U.S. Application Data
(63) Continuation of application No. PCT/CN2018/122664, filed on Dec. 21, 2018.

(30) Foreign Application Priority Data
Apr. 12, 2018 (CN) 201810326946.5

(51) Int. Cl. H04B 17/10; H04B 17/12; G01R 29/10

(52) U.S. Cl. CPC H04B 17/104; G01R 29/105; H04B 17/12

(57) ABSTRACT

A test method includes transmitting, by a transmit device, N signal sequences using a transmit antenna array, obtaining, from a test device, a phase offset that is of each signal sequence in the signal sequences and that is generated after the signal sequence passes through a channel, adjusting an initial test signal based on the phase offset that is of each signal sequence and that is generated after the signal sequence passes through the channel, to obtain a target test signal in-phase superposed at the test device, where the target test signal includes a plurality of signal sequences obtained by separately performing phase adjustment on the initial test signal based on the phase offset that is of each signal sequence and that is generated after the signal sequence passes through a respective channel, and transmitting the target test signal using the transmit antenna array.

### CROSS-REFERENCE TO RELATED APPLICATIONS

This application is a continuation application of International Patent Application No. PCT/CN2018/122664, filed on Dec. 21, 2018, which claims priority to Chinese Patent Application No. 201810326946.5, filed on Apr. 12, 2018, both of which are hereby incorporated by reference in their entireties.

### TECHNICAL FIELD

This application relates to the field of wireless communications, and in particular, to a test method, a transmit device, a test device, and a test system.

### BACKGROUND

Multiple-input multiple-output (MIMO) is a communications technology in which a plurality of transmit antennas and a plurality of receive antennas are separately used at a transmit end and a receive end such that a signal is transmitted and received using the plurality of antennas at the transmit end and the receive end. An existing MIMO indicator test system includes a far-field test system. In the far-field test system, a distance between a transmit antenna array and a receive antenna cannot be excessively short, and is limited by a distance threshold. The transmit antenna array and the receive antenna need to be placed in an electromagnetic anechoic chamber used to isolate an external electromagnetic signal. Therefore, a length of the electromagnetic anechoic chamber needs to be greater than the distance between the transmit antenna array and the receive antenna. Only when a distance threshold condition is met, signals transmitted by different transmit antennas can be in-phase superposed, at the receive antenna, and the receive antenna can receive a compound signal that can meet a measurement requirement. If this condition is not met, an obtained signal metric value has a very large error, and a test requirement cannot be met and a signal test cannot be accurately performed.

### SUMMARY

In view of this, this application provides a MIMO signal test method and apparatus, to resolve a problem in other approaches that a signal test cannot be accurately performed when a distance between a transmit antenna array and a receive antenna is less than a distance threshold.

According to a first aspect, a test method is provided. The method includes transmitting, by a transmit device, N signal sequences using a transmit antenna array, obtaining, from a test device, a phase offset that is of each signal sequence in the N signal sequences and that is generated after the signal sequence passes through a channel, adjusting an initial test signal based on the phase offset that is of each signal sequence and that is generated after the signal sequence passes through the channel, to obtain a target test signal in-phase superposed at the test device, where the target test signal includes a plurality of signal sequences obtained by separately performing phase adjustment on the initial test signal based on the phase offset that is of each signal sequence and that is generated after the signal sequence passes through the respective channel, and transmitting the target test signal using the transmit antenna array. The N signal sequences are orthogonal to each other, and N is a positive integer greater than 1. The transmit antenna array includes N transmit antenna units. Further, the transmit device transmits the N signal sequences using the N transmit antenna units in the transmit antenna array, and the N transmit antenna units are in a one-to-one correspondence with the N signal sequences.

A phase is a physical quantity that reflects a status of an antenna signal at any moment. At a moment t, the phase of the antenna signal is a location of the moment t in a signal period. In this way, the transmit device performs phase adjustment on the initial test signal, and the phase-adjusted initial test signal can be in-phase superposed at a receive antenna in a short-distance condition such that a valid signal that can meet a test requirement can be received, and a more accurate signal metric of the transmit device can be calculated.

In a possible implementation, the phase offset, the initial test signal, and a signal sequence of the target test signal meet the following formula

$${S}_{t k} = {S}_{t} {e}^{- j Δ {ϕ}_{k}} ,$$

where Sₜₖ is a k^{th} signal sequence in the target test signal, Sₜ is the initial test signal, Δφₖ i is a phase offset that is of the k^{th} signal sequence and that is generated after the k^{th} signal sequence passes through a channel, and k is not greater than N. In this way, a phase offset of each antenna signal may be calculated, and after phase adjustment is performed on all antenna signals according to the foregoing calculation result, all antenna signals can be in-phase superposed at the receive antenna.

In another possible implementation, the method further includes obtaining, by the transmit device from the test device, an attenuation amplitude that is of each signal sequence and that is generated after the signal sequence passes through a channel, and adjusting the initial test signal based on the phase offset and the attenuation amplitude that are of each signal sequence and that are generated after the signal sequence passes through the channel, to obtain the target test signal. According to this implementation, not only phase adjustment can be performed on the test signal, but also an attenuation amplitude of the test signal can be adjusted. Therefore, a more accurate signal metric of the transmit device can be calculated by eliminating an error caused by attenuation of the test signal, and a test application scope is expanded.

In another possible implementation, the phase offset, the attenuation amplitude, the initial test signal, and a signal sequence of the target test signal meet the following formula

$${S}_{tk} = \frac{1}{{α}_{k}} {S}_{t} {e}^{- j {Δϕ}_{k}} ,$$

where Sₜₖ is a k^{th} signal sequence in the target test signal, Sₜ is the initial test signal, αₖ is an attenuation amplitude that is of the k^{th} signal sequence and that is generated after the k^{th} signal sequence passes through a channel, Δφₖ i is a phase offset that is of the k^{th} signal sequence and that is generated after the k^{th} signal sequence passes through a channel, and k is not greater than N. In this way, a method for calculating a phase offset and an attenuation amplitude is provided, and all antennas signals can be in-phase superposed at the receive antenna.

In another possible implementation, the N signal sequences are N signal sequences selected from an orthogonal sequence, and the orthogonal sequence is an m sequence, a Golden sequence, a Walsh sequence, a large area synchronous (LAS) sequence, a Golay sequence, or a Kasami sequence.

In another possible implementation, the transmitting, by a transmit device, N signal sequences using a transmit antenna array includes simultaneously transmitting, by the transmit device, the N signal sequences using the transmit antenna array, and the transmitting, by the transmit device, the target test signal using the transmit antenna array includes simultaneously transmitting, by the transmit device, the target test signal using the transmit antenna array, where the target test signal includes the N signal sequences.

According to a second aspect, a test method is provided. The method includes receiving, by a test device, a first signal using a receive antenna, where the first signal is a channel response to N signal sequences sent by a transmit device using a transmit antenna array, and the N signal sequences are orthogonal to each other, determining, by the test device based on the first signal, a phase offset that is of each signal sequence in the N signal sequences and that is generated after the signal sequence passes through a respective channel, sending, by the test device to the transmit device, the phase offset that is of each signal sequence and that is generated after the signal sequence passes through the respective channel, receiving, by the test device, a second signal using the receive antenna, where the second signal is a channel response to a target test signal, and the target test signal includes a plurality of signal sequences obtained by adjusting, by the transmit device, an initial test signal based on the phase offset that is of each signal sequence and that is generated after the signal sequence passes through the channel, and calculating, by the test device, a signal metric of the transmit device based on the second signal. In this way, the test device may calculate a phase offset of a signal sequence transmitted by each transmit antenna unit. After obtaining the phase offset, the transmit device performs, based on the phase offset, phase adjustment on the test signal transmitted by the transmit antenna array, where the phase-adjusted target test signal passes through different distances and can be in-phase superposed at the receive antenna in a short-distance condition, to obtain a valid signal that meets a test requirement, and calculate a more accurate signal metric of the transmit device.

In another possible implementation, the method further includes determining, by the test device based on the first signal, an attenuation amplitude that is of each signal sequence and that is generated after the signal sequence passes through a channel, and sending, to the transmit device, the attenuation amplitude that is of each signal sequence and that is generated after the signal sequence passes through the channel.

According to a third aspect, a transmit device is provided. The transmit device includes the transmit device according to the first aspect or the possible implementations of the first aspect.

According to a fourth aspect, a test device is provided. The test device includes the test device according to the second aspect or the possible implementations of the second aspect.

According to a fifth aspect, a test system is provided. The test system includes the transmit device provided in the third aspect and the test device provided in the fourth aspect.

According to a sixth aspect, a computer-readable storage medium is provided. The computer-readable storage medium stores an instruction. When the instruction runs on a computer, the computer is enabled to perform the method according to any one of the first aspect or the possible implementations of the first aspect.

According to a seventh aspect, a computer-readable storage medium is provided. The computer-readable storage medium stores an instruction. When the instruction is run on a computer, the computer is enabled to perform the method according to any one of the second aspect or the possible implementations of the second aspect.

According to an eighth aspect, a computer program product that includes an instruction is provided. When the computer program product runs on a computer, the computer is enabled to perform the method according to the first aspect or the second aspect.

It can be learned from the foregoing descriptions, the embodiments of this application have the following advantages

After the N signal sequences are transmitted using the N transmit antennas, the phase offset of each signal sequence can be determined based on the first signal corresponding to the N signal sequences, and then phase adjustment is performed on the initial test signal based on the phase offset. In this way, the test signal after phase adjustment can be in-phase superposed at the receive antenna, to obtain a valid signal and further calculate the signal metric of the transmit device. Therefore, an accurate test signal can be implemented without being limited by a distance threshold, and costs of constructing an electromagnetic anechoic chamber can be controlled.

### BRIEF DESCRIPTION OF DRAWINGS

FIG. 1 is a schematic diagram of a MIMO test system.

FIG. 2 is a schematic diagram of a transmit antenna array and a receive antenna in an electromagnetic anechoic chamber.

FIG. 3 is a flowchart of a test method according to an embodiment of this application.

FIG. 4 is a schematic diagram of a transmit device according to an embodiment of this application.

FIG. 5 is a schematic diagram of a test device according to an embodiment of this application.

FIG. 6 is a schematic diagram of a MIMO test system according to an embodiment of this application.

FIG. 7 is another schematic diagram of a structure of a transmit device according to an embodiment of this application.

FIG. 8 is another schematic diagram of a structure of a test device according to an embodiment of this application.

### DESCRIPTION OF EMBODIMENTS

A method for testing a transmit device provided in this application is mainly applied to a MIMO test system.

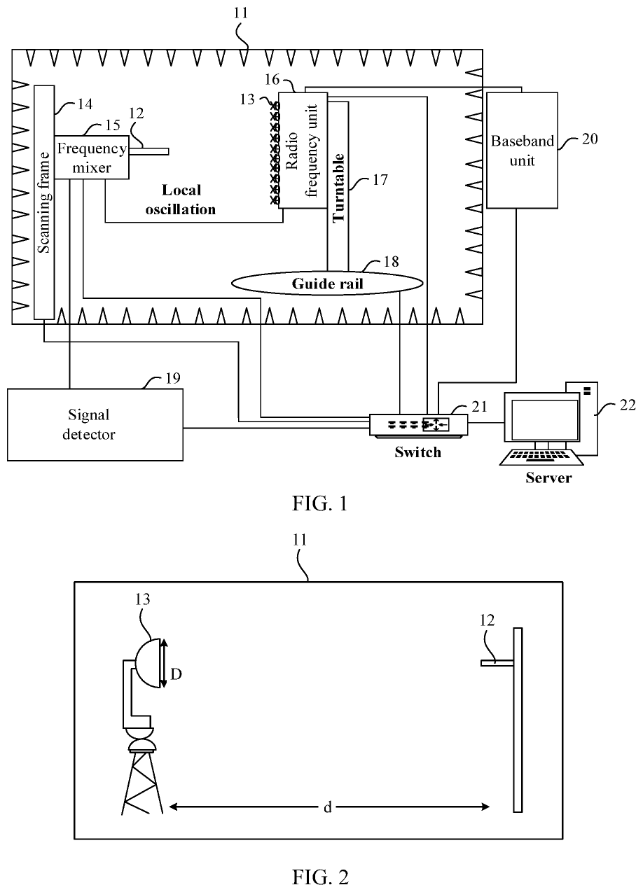

FIG. 1 is a schematic diagram of a specific embodiment of a MIMO test system. The MIMO test system includes an electromagnetic anechoic chamber 11, a scanning frame 14 disposed in the electromagnetic anechoic chamber 11, a frequency mixer 15 and a receive antenna 12 that are fixed on the scanning frame, a turntable 17, a radio frequency unit 16 and a transmit antenna array 13 that are fixed on the turntable, and a guide rail 18 for sliding the turntable 17. In addition, the MIMO test system further includes a signal detector 19 connected to the frequency mixer 15 and the radio frequency unit 16, a baseband unit 20 connected to the radio frequency unit 16, a switch 21, and a server 22. The scanning frame 14, the frequency mixer 15, the radio frequency unit 16, the signal detector 19, the baseband unit 20, and the server 22 are all connected to the switch 21.

The electromagnetic anechoic chamber 11 is an enclosed shielding chamber, and is configured to screen an electromagnetic signal outside the electromagnetic anechoic chamber 11. The baseband unit 20 may be disposed in the electromagnetic anechoic chamber 11, or may be disposed outside the electromagnetic anechoic chamber 11.

A local-frequency signal of the radio frequency unit 16 keeps consistent with that of the frequency mixer 15. In the frequency mixer 15, the local-frequency signal and a high-frequency signal are mixed to generate an intermediate frequency.

A signal is received using the receive antenna 12. The frequency mixer 15 performs frequency mixing on the received signal, and then transmits the signal to the signal detector 19 (for example, a signal source, a spectrum analyzer, or a power meter). The signal detector 19 and/or the server 22 calculate the received signal, to obtain a value of each signal metric. The signal metric may be at least one of effective isotropic sensitivity (EIS), an error vector magnitude (EVM), an adjacent channel leakage ratio (ACLR), equivalent isotropic radiated power (EIRP), and a bit error rate (BER).

In other approaches, a MIMO test system includes a transmit device configured to transmit a MIMO signal and a test device configured to receive a MIMO signal. An antenna array of a MIMO device includes N mutually independent antenna units, and each antenna unit may be an antenna or an antenna bay. When the antenna unit is an antenna bay, phases of signals transmitted by all antennas in the antenna bay are always consistent. A phase is a physical quantity that reflects a status of an antenna signal at any moment. At a moment t, the phase of the antenna signal is a location of the moment tin a signal period.

The following describes, based on the electromagnetic anechoic chamber 11 shown in FIG. 1, a restrictive condition of the electromagnetic anechoic chamber 11. Referring to FIG. 2, in the electromagnetic anechoic chamber 11, an array aperture of the transmit antenna array 13 is denoted as D, a distance between the transmit antenna array 13 and the receive antenna 12 is denoted as d, and a wavelength of a test signal is denoted as 2. In this case, the following condition needs to be met during the test d≥2D²/λ. If this condition is met, signals transmitted by different transmit antennas can be in-phase superposed at a receive antenna, on signals transmitted by different transmit antennas, and the receive antenna may receive a compound signal that can meet a measurement requirement. If this condition is not met, a phase difference between different antennas signals is large at the receive antenna. In this case, an obtained signal metric value differs greatly from that measured in a far-field test environment, that is, an error is very large, and the test requirement cannot be met.

For example, a wavelength of 5 gigahertz (GHz) is approximately 6 centimeters (cm). If an array aperture of the antenna array is 60 cm, the distance d between the transmit antenna array and the receive antenna array needs to be greater than 12 meters (m). If the array aperture of the antenna array is 1 m, the distance d between the transmit antenna array and the receive antenna array needs to be greater than 33.34 m. Therefore, it can be seen that the space of the anechoic chamber in the far-field test system is limited by the distance between the transmit antenna array and the receive antenna array. On the one hand, it is costly to build a large anechoic chamber. On the other hand, as antennas in an antenna array increase, an aperture of the antenna array also becomes larger, and the space of the anechoic chamber needs to be larger. A previous anechoic chamber cannot meet a subsequent antenna measurement condition.

To resolve the foregoing problem, this application provides a signal test method such that signal measurement can be implemented in a condition of d<2 D²/λ, that is, within a distance threshold. The following describes in detail the signal test method provided in this application.

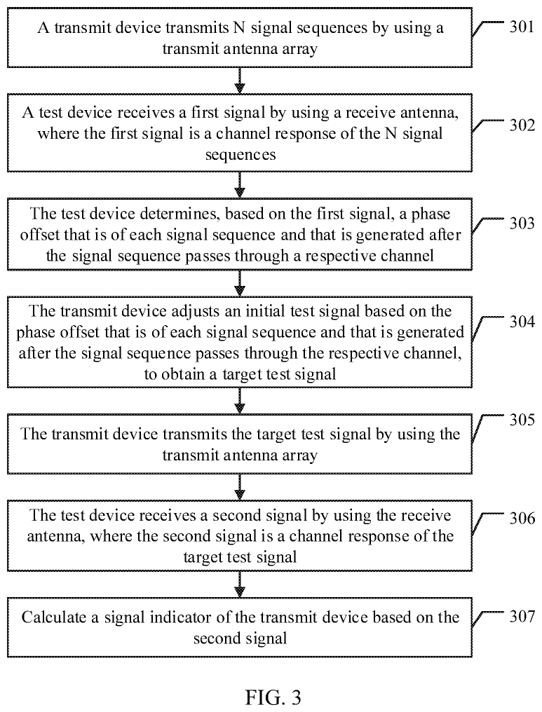

Referring to FIG. 3, in an embodiment, a signal test method provided in this application includes the following steps.

Step 301 A transmit device transmits N signal sequences using a transmit antenna array.

In this embodiment, the transmit antenna array of the transmit device includes N transmit antenna units, where N is a positive integer greater than 1. The transmit antenna array may include N antennas, or may include N antenna bays. When the transmit antenna array includes N antennas, a phase of a signal to be transmitted by each antenna is independently adjustable. When the transmit antenna array includes N antenna bays, each antenna bay includes a plurality of antennas, and phases of signals to be transmitted by all antennas in each antenna bay keep consistent.

The N signal sequences are orthogonal to each other. Signal sequences that are orthogonal to each other are also referred to as a code group. Each code group includes m code words, and the code words are used to represent a binary character string. The N signal sequences may be N signal sequences selected from an orthogonal sequence. The orthogonal sequence may be an m sequence, a Golden sequence, a Walsh sequence, a LAS sequence, a Golay sequence, a Kasami sequence, or another orthogonal sequence. It may be understood that a quantity of signal sequences is the same as a quantity of transmit antenna units.

Step 302 A test device receives a first signal using a receive antenna, where the first signal is a channel response to the N signal sequences.

Because the N signal sequences are orthogonal to each other, that is, the N signal sequences are not correlated, a channel from the N transmit antenna units to the receive antenna may be considered as N independent channels.

A transmitted k^{th} signal sequence is denoted as Cₖ, and a received k^{th} signal sequence is denoted as Cₖ′. In an electromagnetic anechoic chamber, the transmitted signal sequence Cₖ and the received signal sequence Cₖ′meet the following formula

$${C}_{k}^{′} = {α}_{k} \cdot {e}^{j Δ {ϕ}_{k}} ,$$

where αₖ is an attenuation amplitude that is of the k^{th} signal sequence and that is generated after the k^{th} signal sequence passes through a channel, and Δφₖ i is a phase offset that is of the k^{th} signal sequence and that is generated after the k^{th} signal sequence passes through a channel.

For example, the N signal sequences are {C₁, C₂, . . . , Cₙ}, and the first signal Cᵣ and the N signal sequences meet the following formula

$${C}_{r} = {α}_{1} {C}_{1} {e}^{j Δ {ϕ}_{2}} + … + {α}_{n} {C}_{n} {e}^{j Δ {ϕ}_{n}} ,$$

where αₙ is an attenuation amplitude that is of the n^{th} signal sequence and that is generated after the n^{th} signal sequence passes through a channel, and Δφₙ is a phase offset that is of the n^{th} signal sequence and that is generated after the n^{th} signal sequence passes through a channel, and so on.

Step 303 The test device determines, based on the first signal, a phase offset that is of each signal sequence and that is generated after the signal sequence passes through a channel.

Further, a correlation operation is performed on the first signal Cᵣ and the N signal sequences, to obtain the phase offset that is of each signal sequence and that is generated after the signal sequence passes through the channel, that is, Δφ₁, Δφ₂, . . . , Δφₙ. Where Cₖ includes m codewords, denoted as C_{k,1}, Cₖ₂, . . . , Cₖₘ. Cₖ* is a conjugate of Cₖ. C₁ is a signal sequence different from Cₖ in the N signal sequences, and codewords included in Cᵢ are denoted as Cᵢ₁, Cᵢ₂, . . . Cᵢₘ Where Cₖ, Cₖ*, Cᵢ meet the following formula

Cₖ·Cₖ*=cₖ₁×cₖ₁*+cₖ₂×cₖ₂*+ . . . +cₖₘ×cₖₘ*=m, and

Cᵢ·Cₖ*=cᵢ₁×cₖ₁*+cᵢ₂×cₖ₂*+ . . . +cᵢₘ×cₖₘ*=0.

Where Cᵣ and Cₖ* meet the following formula

$$\begin{matrix}{C}_{r} \cdot {C}_{k}^{*} = {C}_{1}^{′} \cdot {C}_{k}^{*} + {C}_{2}^{′} \cdot {C}_{k}^{*} + … + {C}_{k}^{′} \cdot {C}_{k}^{*} + … + {C}_{n}^{′} \cdot {C}_{k}^{*} \\ = 0 + 0 + … + {α}_{k} \cdot m \cdot {e}^{j {Δϕ}_{k}} + … + 0 \\ = {α}_{k} \cdot m \cdot {e}^{j Δ {ϕ}_{k}}\end{matrix} .$$

Because m is a known value, the attenuation amplitude and the phase offset that are of each signal sequence and that are generated after the signal sequence passes through the channel may be obtained by decoupling signals of the antennas.

Step 304 The transmit device adjusts an initial test signal based on the phase offset that is of each signal sequence and that is generated after the signal sequence passes through the respective channel, to obtain a target test signal.

Further, the initial test signal is a signal sequence. The signal sequence herein may be a service signal sequence, or may be another type of signal sequence for testing. This is not limited in this application. The target test signal includes a plurality of signal sequences obtained by separately performing phase adjustment on the initial test signal based on the phase offset that is of each signal sequence and that is generated after the signal sequence passes through the respective channel. One signal sequence in the target test signal is obtained by performing phase adjustment on the initial test signal based on one phase offset. The N signal sequences in the target test signal are obtained by performing phase adjustment on the initial test signal based on the N phase offsets.

In an optional embodiment, the N phase offsets are respectively −Δφ₁, −Δ₂, . . . , −Δφₙ, and −Δφₖ is added to a phase of the initial test signal to calculate a phase of the k^{th} signal sequence in the target test signal. k is any positive integer that belongs to [1, N]. In this way, when signal sequences of the target test signal are transmitted from the transmit antenna to the receive antenna, phases of the signal sequences are consistent at the receive antenna.

In another optional embodiment, a phase offset Δφₖ is selected as a reference value, and a difference between each phase offset and the reference value is calculated. The foregoing calculation result is added to the phase of the initial test signal to calculate a phase of each signal sequence in the target test signal.

For example, Δφ₁ₖ=Δφ₁−Δφₖ, where Δφ₁ₖ is a difference between a phase offset of a first signal sequence in the target test signal and the reference value. A phase of a first signal sequence in the target test signal is calculated by adding Δφ₁ₖ to the phase of the initial test signal. By analogy, Δφ₂ₖ, . . . , Δφₙₖ are calculated, to obtain a phase of each signal sequence in the target test signal. That is, when the phase offset of the first signal sequence at the receive antenna is earlier than the reference value by Δt, the phase offset of the first signal sequence at the transmit antenna is delayed by Δt. When the phase offset of the first signal sequence at the receive antenna lags behind the reference value by Δt, the phase offset of the first signal sequence at the transmit antenna is advanced by Δt. In this way, when signal sequences in the target test signal are transmitted from the transmit antenna to the receive antenna, phases of the signal sequences can be consistent at the receive antenna.

In this application, an antenna located in the center of the transmit antenna array may be selected as a target antenna, and a phase offset of a signal sequence to be transmitted by the target antenna is used as the reference value. Alternatively, an antenna located in the middle area of the transmit antenna array is used as a target antenna, and a phase offset of a signal sequence to be transmitted by the target antenna is used as a reference value. It may be understood that a specific antenna in the transmit antenna array that is selected as the target antenna is not limited in this application.

In this way, phase adjustment is performed on the initial test signal based on the phase offset that is of each signal sequence and that is generated after the signal sequence passes through the respective channel such that the test signal after phase adjustment (namely, the target test signal) can be in-phase superposed at the receive antenna.

Optionally, the phase offset, the initial test signal, and the signal sequence of the target test signal meet the following formula

$${S}_{tk} = {S}_{t} {e}^{- j {Δϕ}_{k}} ,$$

where Sₜₖ is the k^{th} signal sequence in the target test signal, Sₜ is the initial test signal, and k is not greater than N.

Step 305 The transmit device transmits the target test signal using the transmit antenna array.

Step 306 The test device receives a second signal using the receive antenna, where the second signal is a channel response to the target test signal.

In an optional embodiment, the target test signal, the second signal, and the phase offset meet the following formula

$$\begin{matrix}{S}_{r} = {α}_{1} {S}_{t 1} {e}^{j Δ {ϕ}_{1}} + {α}_{2} {S}_{t 2} {e}^{j Δ {ϕ}_{2}} + … + {α}_{n} {S}_{tn} {e}^{j Δ {ϕ}_{n}} \\ = {α}_{1} {S}_{t} + {α}_{2} {S}_{t} + … + {α}_{n} {S}_{t} \\ = {\sum }_{i = 1}^{n} {α}_{i} {S}_{t}\end{matrix} ,$$

where i is not greater than n.

Step 307 The test device calculates a signal metric of the transmit device based on the second signal.

It should be noted that α is an attenuation amplitude after a channel is passed through, and Δφ is a phase offset after a channel is passed through. Therefore, αₙ is not only an attenuation amplitude that is of an n^{th} signal sequence and that is generated after the n^{th} signal sequence passes through a channel, but also an attenuation amplitude that is of an n^{th} signal sequence of the target test signal and that is generated after the n^{th} signal sequence passes through a channel. Similarly, Δφₙ is not only a phase offset that is of the n^{th} signal sequence and that is generated after the n^{th} signal sequence passes through a channel, but also a phase offset that is of the n^{th} signal sequence of the target test signal and that is generated after the n^{th} signal sequence passes through a channel.

In a short-distance environment, phase offsets of different antennas at the receive antenna can be calculated according to the formulas provided in this application, and then corresponding phase adjustment is performed based on the phase offsets such that after passing through transmission paths of different lengths, antenna signals can be in-phase superposed at the receive antenna. This resolves a problem in other approaches that a large error is caused because a phase difference at the receive antenna is excessively large, and a test requirement cannot be met. Because all signal sequences of the target test signal are transmitted to form the second signal at the receive antenna, an accurate and reliable signal metric may be calculated based on the second signal.

In other approaches, when transmitting N antenna signals using N antennas, to avoid signal interference, the transmit device transmits one antenna signal each time using a single antenna. In this way, although signal interference is avoided, it takes a relatively long time. In this application, N transmit antennas may be used to simultaneously transmit N antenna signals, to improve test efficiency.

In an optional embodiment, step 301 further includes simultaneously transmitting, by the transmit device, the N signal sequences using the transmit antenna array.

In this embodiment, the N signal sequences are orthogonal to each other. Because interference between orthogonal signals is very small, after receiving the compound signal obtained by in-phase superposing the N signal sequences, the test device may still decouple the compound signal to obtain a signal parameter of each antenna signal. Therefore, a time used for transmitting a signal sequence is reduced, and test efficiency can be improved.

In another optional embodiment, step 305 further includes simultaneously transmitting, by the transmit device using the transmit antenna array, the N signal sequences included in the target test signal.

In this embodiment, the N signal sequences included in the target test signal are orthogonal to each other. Because interference between orthogonal signals is very small, after receiving the compound signal obtained by in-phase superposing the N signal sequences, the test device may still decouple the compound signal to obtain a signal parameter of each antenna signal. Therefore, a time used for transmitting a signal sequence is reduced, and test efficiency can be improved.

It should be noted that the transmit device may simultaneously transmit the N signal sequences, and transmit, at different time points, the N signal sequences included in the target test signal. Alternatively, the transmit device may transmit the N signal sequences at different time points, and simultaneously transmit the N signal sequences included in the target test signal. Alternatively, the transmit device may simultaneously transmit the N signal sequences, and simultaneously transmit the N signal sequences included in the target test signal.

It should be noted that in addition to phase adjustment on a test signal, signal strength of the test signal may also be adjusted. Details are described below.

In another optional embodiment, the method for testing a MIMO signal further includes determining, based on the first signal, an attenuation amplitude that is of each signal sequence and that is generated after the signal sequence passes through a channel, and step 304 includes adjusting the initial test signal based on the phase offset and the attenuation amplitude that are of each signal sequence and that are generated after the signal sequence passes through the channel, to obtain the target test signal.

In this embodiment, the phase offset, the initial test signal, and the signal sequence of the target test signal meet the following formula

$${S}_{tk} = \frac{1}{{α}_{k}} {S}_{t} {e}^{- j {Δϕ}_{k}} .$$

The target test signal, the second signal, and the phase offset meet the following formula

$$\begin{matrix}{S}_{r} = {α}_{1} {S}_{t 1} {e}^{j Δ {ϕ}_{1}} + {α}_{2} {S}_{t 2} {e}^{j Δ {ϕ}_{2}} + … + {α}_{n} {S}_{tn} {e}^{j {Δϕ}_{n}} \\ = {S}_{t} + {S}_{t} + … + {S}_{t} \\ = {nS}_{t}\end{matrix} ,$$

where Sₜₖ is the k^{th} signal sequence in the target test signal, Sₜ is the initial test signal, αₖ is an attenuation amplitude that is of the k^{th} signal sequence and that is generated after the k^{th} signal sequence passes through a channel, and k is not greater than N.

In this embodiment, the N signal sequences of the target test signal are in-phase superposed at the receive antenna such that the receive antenna can receive a signal that meets a test requirement. In this way, not only phase adjustment can be performed on the test signal, but also an attenuation amplitude of the test signal can be adjusted, thereby expanding a test application scope.

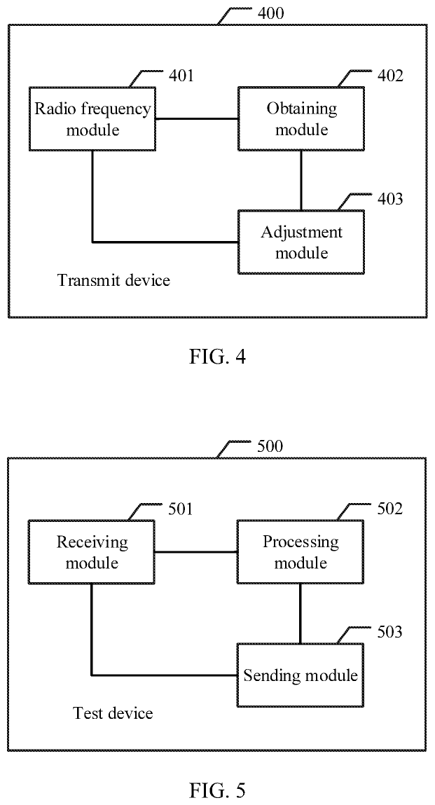

Referring to FIG. 4, in an embodiment, a transmit device 400 provided in this application includes a radio frequency module 401 configured to transmit N signal sequences using a transmit antenna array, where the N signal sequences are orthogonal to each other, N is a positive integer greater than 1, the radio frequency module 401 may be further a radio frequency unit (Radio Remote Unit), for example, a radio frequency unit 16, and may include an intermediate frequency module, a transceiver module, a power amplifier, and a filter module, the digital intermediate frequency module is configured for modulation and demodulation of optical transmission, digital up- and down-conversion, analog to digital (A/D) conversion, and the like, the transceiver module completes conversion from an intermediate frequency signal to a radio frequency signal, and then the power amplifier and the filter module transmit the radio frequency signal using an antenna port, an obtaining module 402 configured to obtain, from a test device, a phase offset that is of each signal sequence and that is generated after the signal sequence passes through a channel, where the test device is configured to test a signal metric of the transmit device, and the obtaining module 402 may further include an input/output (I/O) interface and a corresponding data storage component, and an adjustment module 403, further configured to adjust an initial test signal based on the phase offset that is of each signal sequence and that is generated after the signal sequence passes through the channel, to obtain a target test signal in-phase superposed at the test device, where the target test signal includes a plurality of signal sequences obtained by separately performing phase adjustment on the initial test signal based on the phase offset that is of each signal sequence and that is generated after the signal sequence passes through the respective channel, during specific implementation, a digital signal may be adjusted using a device such as a device processor, a digital signal processor (DSP), a field-programmable gate array (FPGA), or an external device, and an analog signal may be adjusted using an external phase adjustment device and an attenuator.

The radio frequency module 401 is further configured to transmit the target test signal using the transmit antenna array.

In an optional embodiment, the phase offset, the initial test signal, and the signal sequence of the target test signal meet the following formula

$${S}_{t k} = {S}_{t} {e}^{- {j}^{Δ} {ϕ}_{k}} ,$$

where Sₜₖ is a k^{th} signal sequence in the target test signal, Sₜ is the initial test signal, Δφₖ is a phase offset that is of the k^{th} signal sequence and that is generated after the k^{th} signal sequence passes through a channel, and k is not greater than N.

In another optional embodiment, the obtaining module 402 is further configured to obtain, from the test device, an attenuation amplitude that is of each signal sequence and that is generated after the signal sequence passes through a channel, and the radio frequency module 401 is further configured to adjust the initial test signal based on the phase offset and the attenuation amplitude that are of each signal sequence and that are generated after the signal sequence passes through the channel, to obtain the target test signal.

In another optional embodiment, the phase offset, the attenuation amplitude, the initial test signal, and the signal sequence of the target test signal meet the following formula

$${S}_{tk} = \frac{1}{{α}_{k}} {S}_{t} {e}^{- j {Δϕ}_{k}} .$$

where Sₜₖ is a k^{th} signal sequence in the target test signal, Sₜ is the initial test signal, Δₖ is an attenuation amplitude that is of the k^{th} signal sequence and that is generated after the k^{th} signal sequence passes through a channel, Δφₖ, is a phase offset that is of the k^{th} signal sequence and that is generated after the k^{th} signal sequence passes through a channel, and k is not greater than N.

In another optional embodiment, the radio frequency module 401 is further configured to simultaneously transmit the N signal sequences using the transmit antenna array, where the N signal sequences are orthogonal to each other.

In another optional embodiment, the radio frequency module 401 is further configured to simultaneously transmit, using the transmit antenna array, N signal sequences included in the target test signal.

Referring to FIG. 5, in an embodiment, a test device 500 provided in this application includes a receiving module 501 configured to receive a first signal using a receive antenna, where the first signal is a channel response to N signal sequences sent by a transmit device using a transmit antenna array, the N signal sequences are orthogonal to each other, and the receiving module 501 may be further a component such as a radio frequency receiving channel or an A/D converter, a processing module 502 configured to determine, based on the first signal, a phase offset that is of each signal sequence in the N signal sequences and that is generated after the signal sequence passes through a channel, and the processing module 502 may be further a central processing unit (CPU), an FPGA, a DSP, or another dedicated circuit having a signal processing function, and a sending module 503 configured to send, to the transmit device, the phase offset that is of each signal sequence and that is generated after the signal sequence passes through the channel, where in an embodiment, the test device may send the offset to a to-be-tested MIMO device in a wired connection manner such as a serial port or an Ethernet port or in a wireless transmission manner.

The receiving module 501 is further configured to receive a second signal using the receive antenna, where the second signal is a channel response to the target test signal, and the target test signal is obtained by adjusting, by the transmit device, the initial test signal based on the phase offset that is of each signal sequence and that is generated after the signal sequence passes through the channel, and the processing module 502 is further configured to calculate a signal metric of the transmit device based on the second signal.

In an optional embodiment, the processing module 502 is further configured to determine, based on the first signal, an attenuation amplitude that is of each signal sequence and that is generated after the signal sequence passes through a channel, and the sending module 503 is further configured to send, to the transmit device, the attenuation amplitude that is of each signal sequence and that is generated after the signal sequence passes through the respective channel.

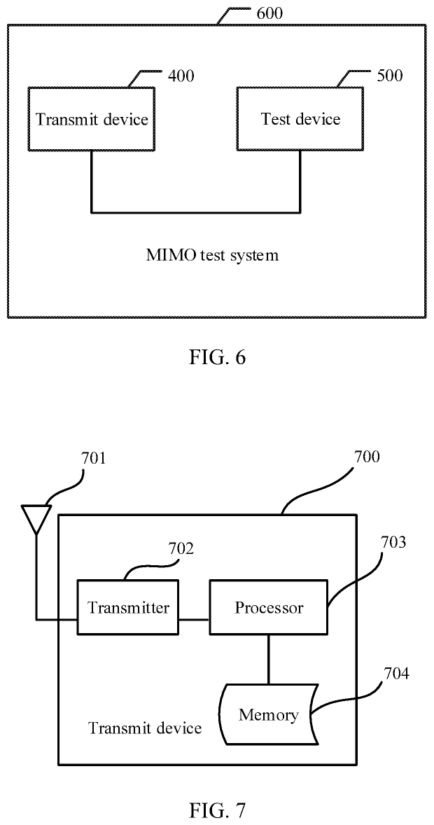

Referring to FIG. 6, in an embodiment, a MIMO test system 600 provided in this application includes a transmit device 400 and a test device 500.

The transmit device 400 is the transmit device in the embodiment shown in FIG. 4 or the foregoing optional embodiment. The test device 500 is the test device in the embodiment shown in FIG. 5 or the foregoing optional embodiment.

The following describes the transmit device and the test device in this application from a perspective of a hardware device.

Referring to FIG. 7, in another embodiment, a transmit device 700 provided in this application includes a transmit antenna array 701, a transmitter 702, a processor 703, and a memory 704.

The transmit antenna array 701 is connected to the transmitter 702. Both the transmitter 702 and the memory 704 are connected to the processor 703, for example, may be connected to the processor 703 using a bus. Certainly, the transmit device 700 may further include general components such as a receiver, a baseband processing component, an intermediate radio frequency processing component, an I/O apparatus, and a communications interface. This is not limited herein in this embodiment. The receiver and the transmitter may be integrated to constitute a transceiver.

The processor 703 may be a general-purpose processor, including a CPU, a network processor (NP), or the like. Alternatively, the processor may be a DSP, an application-specific integrated circuit (ASIC), a FPGA, another programmable logic component, or the like.

The memory 704 is configured to store a program. Further, the program may include program code, and the program code includes a computer operation instruction. The memory 802 may include a random-access memory (RAM), or may further include a non-volatile memory (NVM), for example, at least one disk storage.

During an implementation, the transmitter 702 is configured to transmit N signal sequences using the transmit antenna array 701, where the N signal sequences are orthogonal to each other, and N is a positive integer greater than 1, the processor 703 is configured to obtain, from a test device, a phase offset that is of each signal sequence and that is generated after the signal sequence passes through a channel, and the processor 703 is further configured to adjust an initial test signal based on a phase offset that is of each signal sequence and that is generated after the signal sequence passes through a channel, to obtain a target test signal in-phase superposed at the test device, where the target test signal includes a plurality of signal sequences obtained by separately performing phase adjustment on the initial test signal based on the phase offset that is of each signal sequence and that is generated after the signal sequence passes through the respective channel.

The transmitter 702 is further configured to transmit the target test signal using the transmit antenna array 701.

The processor 703 executes program code stored in the memory 704, to implement functions of the transmit device in the embodiment shown in FIG. 3 or the foregoing optional embodiment.

In another implementation, the transmitter 702 may implement a function of the radio frequency module 401 in the embodiment shown in FIG. 4. The processor 703 may implement functions of the obtaining module 402 and the adjustment module 403 in the embodiment shown in FIG. 4.

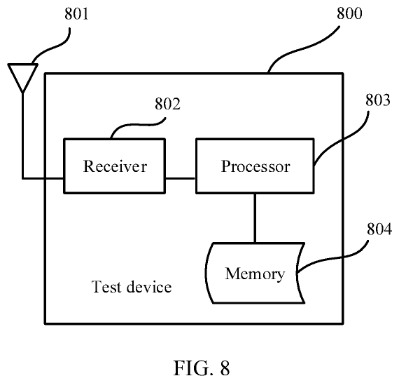

Referring to FIG. 8, in another embodiment, a test device 800 provided in this application includes a receive antenna 801, a receiver 802, a processor 803, and a memory 804.

The receive antenna 801 is connected to the receiver 802. Both the receiver 802 and the memory 804 are connected to the processor 803, for example, may be connected to the processor 803 using a bus. Certainly, the test device 800 may further include general components such as a transmitter, a baseband processing component, an intermediate radio frequency processing component, an I/O apparatus, and a communications interface. This is not limited herein in this embodiment. The receiver and the transmitter may be integrated to constitute a transceiver.

The processor 803 may be a general-purpose processor, including a CPU, an NP, or the like. Alternatively, the processor may be a DSP, an ASIC, an FPGA, another programmable logic device, or the like.

The memory 804 is configured to store a program. Further, the program may include program code, and the program code includes a computer operation instruction. The memory 804 may include a RAM, or may further include an NVM, for example, at least one disk storage. The processor 803 executes program code stored in the memory 804, to implement functions of the test device in the embodiment shown in FIG. 3 or the foregoing optional embodiment.

During an implementation, the receiver 802 is configured to receive a first signal using the receive antenna 801, where the first signal is a channel response to N signal sequences sent by a transmit device using a transmit antenna array, the N signal sequences are orthogonal to each other, and N is a positive integer greater than 1, the processor 803 is configured to determine, based on the first signal, a phase offset that is of each signal sequence in the N signal sequences and that is generated after the signal sequence passes through a respective channel, the processor 803 is further configured to send, to the transmit device, the phase offset that is of each signal sequence and that is generated after the signal sequence passes through a respective channel, the receiver 802 is further configured to receive a second signal using the receive antenna 801, where the second signal is a channel response to the target test signal, and the target test signal is obtained by adjusting, by the transmit device, the initial test signal based on the phase offset that is of each signal sequence and that is generated after the signal sequence passes through the channel, and the processor 803 is further configured to calculate a signal metric of the transmit device based on the second signal.

In another implementation, the receiver 802 may implement a function of the receiving module in the embodiment shown in FIG. 5 or the foregoing optional embodiment. The processor 803 may implement a function of the processing module 502 in the embodiment shown in FIG. 5. The communications interface may implement a function of the sending module 503 under control of the processor 803.

This application further provides a computer storage medium, including an instruction. When the instruction is executed on a computer, the computer is enabled to perform the method in the foregoing embodiment.

All or some of the foregoing embodiments may be implemented using software, hardware, firmware, or any combination thereof. When software is used to implement the embodiments, the embodiments may be implemented completely or partially in a form of a computer program product.

The computer program product includes one or more computer instructions. When the computer program instructions are loaded and executed on the computer, the procedure or functions according to the embodiments of the present disclosure are all or partially generated. The computer may be a general-purpose computer, a dedicated computer, a computer network, or other programmable apparatuses. The computer instructions may be stored in a computer-readable storage medium or may be transmitted from a computer-readable storage medium to another computer-readable storage medium. For example, the computer instructions may be transmitted from a website, computer, server, or data center to another website, computer, server, or data center in a wired (for example, a coaxial cable, an optical fiber, or a digital subscriber line) or wireless (for example, infrared, radio, or microwave) manner. The computer-readable storage medium may be any usable medium accessible by a computer, or a data storage device, such as a server or a data center, integrating one or more usable media. The usable medium may be a magnetic medium (for example, a floppy disk, a hard disk, or a magnetic tape), an optical medium (for example, a digital versatile disc (DVD)), a semiconductor medium (for example, a solid-state drive (SSD)), or the like.

What is claimed is:

1. A test method, implemented by a transmit device, wherein the test method comprises:
transmitting a first plurality of signal sequences using a transmit antenna array, wherein the first signal sequences are orthogonal to each other;
obtaining, from a test device, a phase offset of each of the first signal sequences after each of the first signal sequences pass through a respective channel;
adjusting an initial test signal based on the phase offset to obtain a target test signal in-phase superposed, wherein the target test signal comprises a second plurality of signal sequences, wherein adjusting the initial test signal comprises separately performing phase adjustment on the initial test signal based on the phase offset; and
transmitting the target test signal using the transmit antenna array.

2. The test method of claim 1, wherein the phase offset, the initial test signal, and a signal sequence of the target test signal are according to the following equation:
$${S}_{t k} = {S}_{t} {e}^{- j Δ {ϕ}_{k}} ,$$
wherein Sₜₖ is a kth signal sequence in one of the second signal sequences in the target test signal, wherein Sₜ is the initial test signal, wherein Δφₖ is a phase offset that is of the kth signal sequence and that is generated after the kth signal sequence passes through a channel, and wherein k is not greater than a quantity of the first signal sequences.

3. The test method of claim 1, further comprising:
obtaining, from the test device, an attenuation amplitude of each of the first signal sequences after each of the first signal sequences passes through the respective channel; and
adjusting the initial test signal to obtain the target test signal based on the phase offset and the attenuation amplitude.

4. The test method of claim 3, wherein the phase offset, the attenuation amplitude, the initial test signal, and a signal sequence of the target test signal are according to the following equation:
$${S}_{tk} = \frac{1}{{α}_{k}} {S}_{t} {e}^{- j {Δϕ}_{k}} ,$$
wherein Sₜₖ is a kth signal sequence in one of the second signal sequences in the target test signal, wherein Sₜ is the initial test signal, wherein αₖ is the attenuation amplitude that is of the kth signal sequence and that is generated after the kth signal sequence passes through a channel, wherein Δφₖ is a phase offset that is of the kth signal sequence and that is generated after the kth signal sequence passes through the channel, and wherein k is not greater than a quantity of the first signal sequences.

5. The test method of claim 1, further comprising selecting the first signal sequences from an orthogonal sequence, wherein the orthogonal sequence is an m sequence.

6. The test method of claim 1, further comprising selecting the first signal sequences from an orthogonal sequence, wherein the orthogonal sequence is a Golden sequence.

7. The test method of claim 1, further comprising selecting the first signal sequences from an orthogonal sequence, and wherein the orthogonal sequence is a Walsh sequence.

8. The test method of claim 1, further comprising selecting the first signal sequences from an orthogonal sequence, wherein the orthogonal sequence is a large area synchronous (LAS) sequence.

9. The test method of claim 1, further comprising selecting the first signal sequences from an orthogonal sequence, wherein the orthogonal sequence is a Golay sequence.

10. The test method of claim 1, further comprising selecting the first signal sequences from an orthogonal sequence, wherein the orthogonal sequence is a Kasami sequence.

11. The test method of claim 1, further comprising transmitting the first signal sequences simultaneously using the transmit antenna array.

12. The test method of claim 1, further comprising transmitting the target test signal simultaneously using the transmit antenna array, wherein the target test signal comprises the first signal sequences.

13. A test method, implemented by a test device, wherein the test method comprises:
receiving a first signal using a receive antenna, wherein the first signal is a first channel response of a first plurality of signal sequences from a transmit device using a transmit antenna array, and wherein the first signal sequences are orthogonal to each other;
determining, based on the first signal, a phase offset of each of the first signal sequences after each of the first signal sequences pass through a respective channel;
sending the phase offset to the transmit device;
receiving a second signal using the receive antenna, wherein the second signal is a second channel response of a target test signal, wherein the target test signal comprises a second plurality of signal sequences;
superposing the target test signal in-phase; and
calculating a signal indicator of the transmit device based on the second signal.

14. The test method of claim 13, further comprising:
determining, based on the first signal, an attenuation amplitude of each of the first signal sequences after each of the first signal sequences pass through the respective channel; and
sending the attenuation amplitude to the transmit device.

15. A transmit device, comprising:
a transmit antenna array;
a transmitter coupled to the transmit antenna array and configured to:
transmit a first plurality of signal sequences using the transmit antenna array, wherein the first signal sequences are orthogonal to each other; and
transmit a target test signal using the transmit antenna array; and
a processor coupled to the transmitter and configured to:
obtain, from a test device, a phase offset of each of the first signal sequences after each of the first signal sequences pass through a respective channel;
adjust an initial test signal based on the phase offset to obtain a target test signal in-phase superposed at the test device, wherein the target test signal comprises a second plurality of signal sequences, wherein adjusting the initial test signal comprises separately performing phase adjustment on the initial test signal based on the phase offset.

16. The transmit device of claim 15, wherein the phase offset, the initial test signal, and a signal sequence of the target test signal are according to the following equation:
$${S}_{t k} = {S}_{t} {e}^{- j {Δϕ}_{k}} ,$$
wherein Sₜₖ is a kth signal sequence in one of the second signal sequences in the target test signal, wherein Sₜ is the initial test signal, wherein Δφₖ is a phase offset that is of the kth signal sequence and that is generated after the kth signal sequence passes through a channel, and wherein k is not greater than a quantity of the first signal sequences.

17. The transmit device of claim 15, wherein the processor is further configured to obtain, from the test device, an attenuation amplitude of each of the first signal sequences after each of the first signal sequences pass through the respective channel, wherein the transmitter is further configured to adjust the initial test signal based on the phase offset and the attenuation amplitude to obtain the target test signal.

18. The transmit device of claim 17, wherein the phase offset, the attenuation amplitude, the initial test signal, and a signal sequence of the target test signal are according to the following equation:
$${S}_{tk} = \frac{1}{{α}_{k}} {S}_{t} {e}^{- j {Δϕ}_{k}} ,$$
wherein Sₜₖ is a kth signal sequence in one of the second signal sequences in the target test signal, wherein Sₜ is the initial test signal, wherein αₖ is the attenuation amplitude that is of the kth signal sequence and that is generated after the kth signal sequence passes through a channel, wherein Δφₖ is a phase offset that is of the kth signal sequence and that is generated after the kth signal sequence passes through the channel, and wherein k is not greater than a quantity of the first signal sequences.

19. The transmit device of claim 15, wherein the transmitter is further configured to transmit the first signal sequences simultaneously using the transmit antenna array, and wherein the first signal sequences are orthogonal to each other.

20. The transmit device of claim 15, wherein the transmitter is further configured to transmit the target test signal simultaneously using the transmit antenna array, and wherein the target test signal comprises the first signal sequences.
